(19) United States
(12) Patent Application Publication
(10) Pub. No.: US 2024/0155873 A1
(43) Pub. Date: May 9, 2024

(54) DISPLAY DEVICE

(71) Applicant: Samsung Display Co., LTD., Yongin-si (KR)

(72) Inventors: HYEONSIK KIM, Yongin-si (KR); YOOLGUK KIM, Yongin-si (KR); JAE-HYUN PARK, Yongin-si (KR); JINWOO LEE, Yongin-si (KR); HEEWOON IM, Yongin-si (KR)

(73) Assignee: Samsung Display Co., LTD., Yongin-si (KR)

(21) Appl. No.: 18/354,727

(22) Filed: Jul. 19, 2023

(30) Foreign Application Priority Data
Nov. 8, 2022 (KR) 10-2022-0147963

(51) Int. Cl. H10K 59/121; H10K 59/131

(52) U.S. Cl. CPC H10K 59/1216; H10K 59/131

(57) ABSTRACT

A display device includes a first capacitor electrode disposed on a substrate, a second capacitor electrode disposed on the first capacitor electrode and constituting a first capacitor together with the first capacitor electrode, a third capacitor electrode disposed on the second capacitor electrode and constituting a second capacitor together with the second capacitor electrode, a first voltage line including a first portion and a second portion spaced apart from the first and second capacitors in a plan view, and a first bridge pattern connecting the first portion and the second portion of the first voltage line. The first voltage line and the third capacitor electrode are disposed in different layers, and the first bridge pattern and the first voltage line are disposed in different layers.

### CROSS-REFERENCE TO RELATED APPLICATION(S)

This application claims priority to and benefits of Korean Patent Application No. 10-2022-0147963 under 35 U.S.C. § 119, filed on Nov. 8, 2022, in the Korean Intellectual Property Office (KIPO), the entire contents of which are incorporated herein by reference.

### BACKGROUND

### 1. Technical Field

Embodiments relate to a display device that provides visual information.

### 2. Description of the Related Art

With the development of information technology, the importance of a display device, which is a connection medium between a user and information, has been highlighted. For example, the use of a display device such as a liquid crystal display device (“LCD”), an organic light emitting display device (“OLED”), a plasma display device (“PDP”), a quantum dot display device, and the like is increasing.

Meanwhile, the display device may include at least one transistor and a light emitting element electrically connected to the at least one transistor. For example, an active layer of the transistor may include amorphous silicon or polycrystalline silicon. Recently, research on a transistor using a metal oxide semiconductor having higher charge mobility than amorphous silicon, lower cost and higher uniformity than polycrystalline silicon has been conducted.

### SUMMARY

Embodiments provide a display device with improved display quality.

A display device according to embodiments of the disclosure may include a first capacitor electrode disposed on a substrate, a second capacitor electrode disposed on the first capacitor electrode and constituting a first capacitor together with the first capacitor electrode, a third capacitor electrode disposed on the second capacitor electrode and constituting a second capacitor together with the second capacitor electrode, a first voltage line including a first portion and a second portion spaced apart from the first and second capacitors in a plan view, and a first bridge pattern electrically connecting the first portion and the second portion of the first voltage line. The first voltage line and the third capacitor electrode may be disposed in different layers, and the first bridge pattern and the first voltage line may be disposed in different layers.

In an embodiment, the first capacitor may be a storage capacitor, and the second capacitor may be a hold capacitor.

In an embodiment, the first, second, and third capacitor electrodes may overlap with each other in a plan view.

In an embodiment, the first voltage line may be a common voltage line to which a common voltage is applied.

In an embodiment, the first bridge pattern may have a C shape in a plan view.

In an embodiment, each of the first bridge pattern and the first voltage line may include a metal having low resistance.

In an embodiment, the display device may further include a second voltage line including a first portion and a second portion spaced apart from the first and second capacitors in a plan view and a second bridge pattern electrically connecting the first portion and the second portion of the second voltage line. The second voltage line and the third capacitor electrode may be disposed in different layers, and the second bridge pattern and the second voltage line may be disposed in different layers.

In an embodiment, the second voltage line may be a reference voltage line to which a reference voltage is applied.

In an embodiment, the second bridge pattern may have a C shape rotated by about 180 degrees in a plan view.

In an embodiment, each of the first bridge pattern and the second bridge pattern may be spaced apart from the first and second capacitors in a plan view.

In an embodiment, each of the second bridge pattern and the second voltage line may include a metal having low resistance.

In an embodiment, the display device may further include a lower metal layer disposed on the substrate, an active layer disposed on the lower metal layer and including a metal oxide semiconductor, a lower gate electrode disposed on the active layer, an upper gate electrode disposed on the lower gate electrode, a lower connection electrode disposed on the upper gate electrode, and an upper connection electrode disposed on the lower connection electrode.

In an embodiment, the first capacitor electrode and the lower metal layer may be disposed in a same layer, the second capacitor electrode and the lower gate electrode may be disposed in a same layer, and the third capacitor electrode and the upper gate electrode may be disposed in a same layer.

In an embodiment, the first voltage line and the lower connection electrode may be disposed in a same layer, and the first bridge pattern and the upper connection electrode may be disposed in a same layer.

In an embodiment, the display device may further include a light emitting element including a pixel electrode, a light emitting layer, and a common electrode sequentially disposed on the upper connection electrode. The light emitting layer may include a light emitting material and a plurality of quantum dots dispersed in the light emitting material.

In an embodiment, the display device may further include a light blocking layer disposed on the light emitting element and including an opening overlapping the light emitting layer in a plan view, and a color filter disposed in the opening.

In an embodiment, the display device may further include a first via insulating layer covering the lower connection electrode, and a second via insulating layer disposed on the first via insulating layer and covering the upper connection electrode. Each of the first via insulating layer and the second via insulating layer may include photosensitive polyimide (PSPI).

A display device according to embodiments of the disclosure may include a first capacitor electrode disposed on a substrate, a second capacitor electrode disposed on the first capacitor electrode and constituting a first capacitor together with the first capacitor electrode, a third capacitor electrode disposed on the second capacitor electrode and constituting a second capacitor together with the second capacitor electrode, a first voltage line including a first portion and a second portion spaced apart from the first and second capacitors in a plan view, each of the first portion and the second portion extending in a first direction, and a first bridge pattern electrically connecting the first portion and the second portion of the first voltage line and spaced apart from the first and second capacitors in a plan view in a second direction intersecting the first direction. The first voltage line and the third capacitor electrode may be disposed in different layers, and the first bridge pattern and the first voltage line may be disposed in different layers.

In an embodiment, the first voltage line may be a common voltage line to which a common voltage is applied.

In an embodiment, the display device may further include a second voltage line including a first portion and a second portion spaced apart from the first and second capacitors in a plan view, each of the first portion and the second portion of the second voltage line extending in the first direction, and a second bridge pattern electrically connecting the first portion and the second portion of the second voltage line and spaced apart from the first and second capacitors in a plan view in the second direction. The second voltage line may include a reference voltage line to which a reference voltage is applied, the second voltage line and the third capacitor electrode may be disposed in different layers, and the second bridge pattern and the second voltage line may be disposed in different layers.

A display device according to an embodiment of the disclosure may include a first capacitor electrode disposed on a substrate, a second capacitor electrode overlapping the first capacitor electrode in a plan view and constituting a first capacitor (e.g., a storage capacitor) together with the first capacitor electrode, a third capacitor electrode overlapping the second capacitor electrode in a plan view and constituting a second capacitor (e.g., a hold capacitor) together with the second capacitor electrode, a voltage line including a first portion and a second portion spaced apart from the first and second capacitors in a plan view, and a bridge pattern disposed on a different layer from the voltage line and electrically connecting the first portion and the second portion of the voltage line. Accordingly, a step difference between an area in which the capacitor is disposed and an area in which the capacitor is not disposed may be improved. In addition, the thickness of the light emitting layer may be readily controlled, and the display quality of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the disclosure.

FIG. 2 is a schematic diagram of equivalent circuit of a sub-pixel of the display device of FIG. 1.

FIG. 3 is a schematic cross-sectional view illustrating the display device of FIG. 1 according to an embodiment.

FIGS. 4, 5, 6, 7, 8, 9, 10, 11, 12, 13, and 14 are layout views for illustrating one sub-pixel of the display device of FIG. 1.

FIG. 15 is an enlarged plan view of area A of FIG. 14.

FIG. 16 is a schematic cross-sectional view taken along line I-I′ of FIG. 15.

FIG. 17 is a schematic cross-sectional view taken along line II-II′ of FIG. 15.

### DETAILED DESCRIPTION OF THE EMBODIMENTS

Hereinafter, a display device according to embodiments of the disclosure will be explained in detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

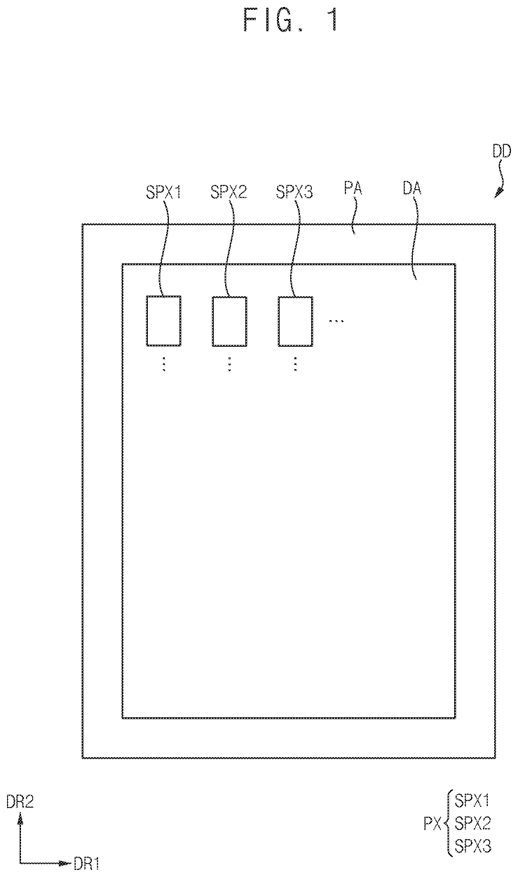

FIG. 1 is a plan view illustrating a display device according to an embodiment of the disclosure.

Referring to FIG. 1, a display device DD according to an embodiment may include a display area DA and a peripheral area PA. The display area DA may be defined as an area capable of displaying an image by generating light or adjusting transmittance of light provided from an external light source. The peripheral area PA may be defined as an area not displaying an image. The peripheral area PA may surround at least a portion of the display area DA. For example, the peripheral area PA may entirely surround the display area DA.

The display device DD may have a rectangular planar shape in a plan view. However, the disclosure is not limited thereto, and the display device DD may have various planar shapes.

Multiple pixels PX may be disposed in the display area DA. As such, the display area DA may display an image by emitting light from the pixels PX.

Each of the pixels PX may include a first sub-pixel SPX1, a second sub-pixel SPX2, and a third sub-pixel SPX3. For example, each of the first sub-pixel SPX1, the second sub-pixel SPX2, and the third sub-pixel SPX3 may include a semiconductor element (e.g., a transistor) and a light emitting element electrically connected to the semiconductor element (e.g., a light emitting diode or the like). The light emitting element may emit light by receiving a signal from the semiconductor element.

In an embodiment, the first sub-pixel SPX1 may be a red sub-pixel that emits red light, the second sub-pixel SPX2 may be a green sub-pixel that emits green light, and the third sub-pixel SPX3 may be a blue sub-pixel that emits blue light. However, the color of light emitted from each of the sub-pixels SPX1, SPX2, and SPX3 is not limited thereto. Although the number of sub-pixels SPX1, SPX2, and SPX3 is shown as three, the disclosure is not limited thereto. For example, each of the pixels PX may further include a fourth sub-pixel that emits white light.

The pixels PX may be arranged in a matrix form in the first direction DR1 and the second direction DR2 intersecting the first direction DR1. Accordingly, each of the first sub-pixel SPX1, the second sub-pixel SPX2, and the third sub-pixel SPX3 may be arranged in a matrix form in the first and second directions DR1 and DR2.

A driver for driving pixels PX may be disposed in the peripheral area PA. For example, the driver may include a data driver, a gate driver, a light emitting driver, a power voltage generator, a timing controller, or the like. The pixels PX may emit light based on signals transmitted from the driver.

In this specification, a plane may be defined by a first direction DR1 and a second direction DR2 intersecting the first direction DR1. For example, the first direction DR1 may be perpendicular to the second direction DR2.

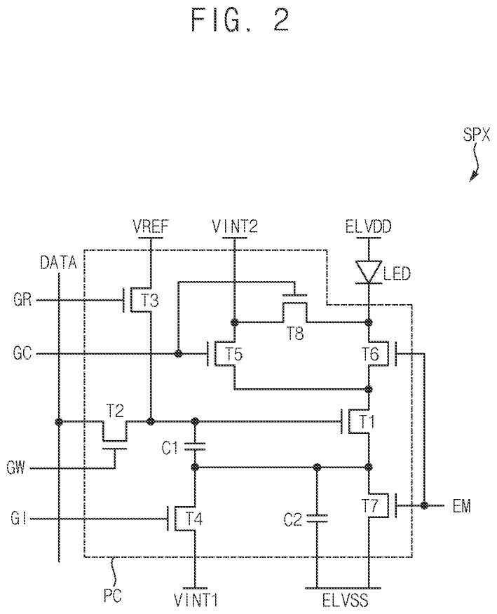

FIG. 2 is a schematic diagram of an equivalent circuit of a sub-pixel of the display device of FIG. 1. For example, the sub-pixel SPX illustrated in FIG. 2 may correspond to one of the first, second, and third sub-pixels SPX1, SPX2, and SPX3 illustrated in FIG. 1.

Referring to FIG. 2, the sub-pixel SPX may include a pixel circuit PC and a light emitting element LED. The pixel circuit PC may be electrically connected to the light emitting element LED. In an embodiment, the pixel circuit PC may include first, second, third, fourth, fifth, sixth, seventh, and eighth transistors T1, T2, T3, T4, T5, T6, T7, and T8, a first capacitor C1, and a second capacitor C2.

The first transistor T1 may include a gate electrode, a first electrode, and a second electrode. For example, the first transistor T1 may be a driving transistor for driving the light emitting element LED. The gate electrode of the first transistor T1 may be connected to a second electrode of the second transistor T2. The first electrode of the first transistor T1 may be connected to a second electrode of the sixth transistor T6. The second electrode of the first transistor T1 may be connected to a first electrode of the seventh transistor T7.

The second transistor T2 may include a gate electrode, a first electrode, and a second electrode. For example, a data voltage DATA may be applied to the first electrode of the second transistor T2. The second electrode of the second transistor T2 may be connected to a gate electrode of the first transistor T1. A first control signal GW may be applied to the gate electrode of the second transistor T2.

The third transistor T3 may include a gate electrode, a first electrode, and a second electrode. For example, the first electrode of the third transistor T3 may be connected to the second electrode of the second transistor T2. A reference voltage VREF may be applied to the second electrode of the third transistor T3. A second control signal GR may be applied to the gate electrode of the third transistor T3.

The fourth transistor T4 may include a gate electrode, a first electrode, and a second electrode. For example, a first initialization voltage VINT1 may be applied to the first electrode of the fourth transistor T4. The second electrode of the fourth transistor T4 may be connected to a first electrode of the seventh transistor T7. A fourth control signal GI may be applied to the gate electrode of the fourth transistor T4.

The fifth transistor T5 may include a gate electrode, a first electrode, and a second electrode. For example, a second initialization voltage VINT2 may be applied to the first electrode of the fifth transistor T5. The second electrode of the fifth transistor T5 may be connected to the first electrode of the first transistor T1. A third control signal GC may be applied to the gate electrode of the fifth transistor T5.

The sixth transistor T6 may include a gate electrode, a first electrode, and a second electrode. For example, the first electrode of the sixth transistor T6 may be connected to a second electrode of the eighth transistor T8. The second electrode of the sixth transistor T6 may be connected to the first electrode of the first transistor T1. A light emitting control signal EM may be applied to the gate electrode of the sixth transistor T6.

The seventh transistor T7 may include a gate electrode, a first electrode, and a second electrode. For example, the first electrode of the seventh transistor T7 may be connected to the second electrode of the first transistor T1. A common voltage ELVSS may be applied to the second electrode of the seventh transistor T7. The light emitting control signal EM may be applied to the gate electrode of the seventh transistor T7.

The eighth transistor T8 may include a gate electrode, a first electrode, and a second electrode. For example, a second initialization voltage VINT2 may be applied to the first electrode of the eighth transistor T8. The second electrode of the eighth transistor T8 may be connected to the first electrode of the sixth transistor T6. The gate electrode of the eighth transistor T8 may be connected to the gate electrode of the fifth transistor T5.

The first capacitor C1 may include a first electrode and a second electrode. For example, the first electrode of the first capacitor C1 may be connected to the gate electrode of the first transistor T1. The second electrode of the first capacitor C1 may be connected to the second electrode of the fourth transistor T4. In an embodiment, the first capacitor C1 may be a storage capacitor.

The second capacitor C2 may include a first electrode and a second electrode. For example, the first electrode of the second capacitor C2 may be connected to the second electrode of the first capacitor C1. The common voltage ELVSS may be applied to the second electrode of the second capacitor C2. In an embodiment, the second capacitor C2 may be a hold capacitor.

The light emitting element LED may include an anode electrode and a cathode electrode. For example, a driving voltage ELVDD may be applied to the anode electrode of the light emitting element LED. The cathode electrode of the light emitting element LED may be connected to the first electrode of the sixth transistor T6. A voltage level of the driving voltage EVLDD may be higher than a voltage level of the common voltage ELVSS.

However, although the sub-pixel SPX of the disclosure has been described as including eight transistors and two capacitors, the configuration of the disclosure is not limited thereto. For example, the sub-pixel SPX may have a configuration including at least one transistor and at least one capacitor.

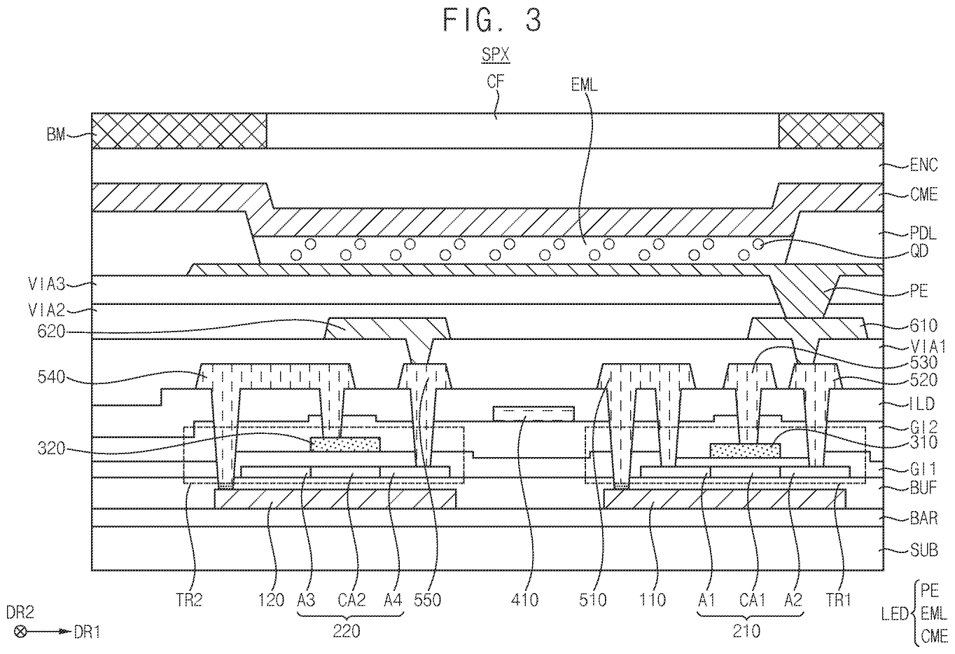

FIG. 3 is a schematic cross-sectional view illustrating the display device of FIG. 1 according to an embodiment. For example, FIG. 3 is a view schematically illustrating a cross-section of one sub-pixel SPX according to an embodiment. The one sub-pixel SPX may correspond to any one of the first, second, and third sub-pixels SPX1, SPX2, and SPX3 illustrated in FIG. 1.

Referring to FIG. 3, the display device DD according to an embodiment may include a substrate SUB, a barrier layer BAR, first and second lower metal layers 110 and 120, a buffer layer BUF, first and second active layers 210 and 220, a first gate insulating layer GI1, first and second lower gate electrodes 310 and 320, a second gate insulating layer GI2, an upper gate electrode 410, an interlayer insulating layer ILD, first, second, third, fourth, and fifth lower connection electrodes 510, 520, 530, 540, and 550, a first via insulating layer VIA1, first and second upper connection electrodes 610 and 620, a second via insulating layer VIA2, a third via insulating layer VIA3, a pixel defining layer PDL, a pixel electrode PE, a light emitting layer EML, a common electrode CME, an encapsulation layer ENC, a light blocking layer BM, and a color filter CF.

The substrate SUB may include a transparent material or an opaque material. In an embodiment, the substrate SUB may include a transparent resin. Examples of the transparent resin may include polyimide and the like. In an embodiment, the substrate SUB may include a quartz, a synthetic quartz, a calcium fluoride, an F-doped quartz, a soda-lime glass, a non-alkali glass, or the like. These may be used alone or in combination with each other.

The barrier layer BAR may be disposed on the substrate SUB. The barrier layer BAR may block permeation of outside air. For example, the barrier layer BAR may include an inorganic material such as silicon oxide, silicon nitride, and the like.

The first and second lower metal layers 510 and 520 may be disposed on the barrier layer BAR. Each of the first and second lower metal layers 510 and 520 may include a metal, an alloy, a conductive metal oxide, a transparent conductive material, the like, or a combination thereof. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), indium (In), and the like. Examples of the conductive metal oxide may include indium tin oxide (ITO), indium zinc oxide (IZO), indium tin zinc oxide (ITZO), and the like. Each of these may be used alone or in combination with each other. The first and second lower metal layers 510 and 520 may include a same material and may be disposed in a same layer.

The buffer layer BUF may be disposed on the barrier layer BAR and the first and second lower metal layers 510 and 520. The buffer layer BUF may cover the first and second lower metal layers 110 and 120. The buffer layer BUF may prevent diffusion of impurities from the substrate SUB into the first and second active layers 210 and 220. The buffer layer BUF may control the transfer rate of heat generated in the process of forming the first and second active layers 210 and 220. For example, the buffer layer BUF may include an inorganic material such as silicon oxide, silicon nitride, and the like.

The first and second active layers 210 and 220 may be disposed on the buffer layer BUF. In an embodiment, each of the first and second active layers 210 and 220 may include a metal oxide semiconductor. The metal oxide semiconductor may include a binary compound (ABₓ), a ternary compound (ABₓC_{y}), a quaternary compound (ABₓC_{y}D_{z}), or the like including indium (In), zinc (Zn), gallium (Ga), tin (Sn), titanium (Ti), aluminum (Al), hafnium (Hf), zirconium (Zr), magnesium (Mg), or the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), or the like. These may be used alone or in combination with each other.

The first and second active layers 210 and 220 may include a same material and may be disposed in a same layer.

The first active layer 210 may include a first area A1, a second area A2, and a first channel area CAL The first channel area CA1 may be positioned between the first area A1 and the second area A2. For example, each of the first area A1 and the second area A2 may be defined as a doped area doped with an impurity.

The second active layer 220 may include a third area A3, a fourth area A4, and a second channel area CA2. The second channel area CA2 may be positioned between the third area A3 and the fourth area A4. For example, each of the third area A3 and the fourth area A4 may be defined as a doped area doped with an impurity.

The first gate insulating layer GI1 may be disposed on the buffer layer BUF and the first and second active layers 210 and 220. The first gate insulating layer GI1 may cover the first and second active layers 210 and 220. For example, the first gate insulating layer GI1 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other.

The first and second lower gate electrodes 310 and 320 may be disposed on the first gate insulating layer GI1. The first lower gate electrode 310 may overlap the first channel area CA1 of the first active layer 210 in a plan view, and the second lower gate electrode 320 may overlap the second channel area CA2 of the second active layer 220 in a plan view. For example, each of the first and second lower gate electrodes 310 and 320 may include a metal, an alloy, a conductive metal oxide, a transparent conductive material, or the like. These may be used alone or in combination with each other. The first and second lower gate electrodes 310 and 320 may include a same material and may be disposed in a same layer.

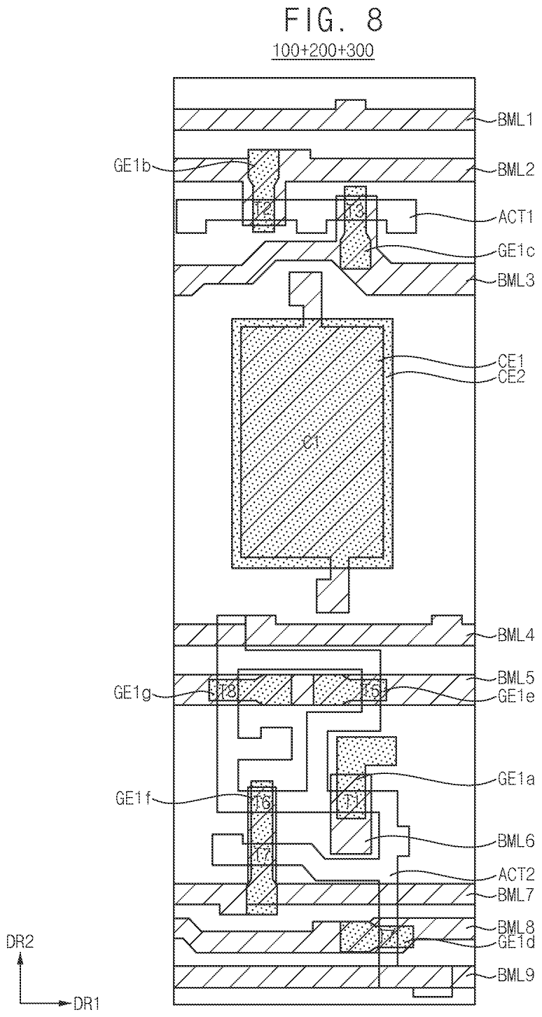

Accordingly, a first semiconductor element TR1 including the first active layer 210 and the first lower gate electrode 310 may be defined, and a second semiconductor element TR2 including the second active layer 220 and the second lower gate electrode 320 may be defined. For example, the first semiconductor element TR1 may be a driving transistor, and the second semiconductor element TR2 may be a switching transistor. The first semiconductor element TR1 may correspond to the first transistor T1 illustrated in FIGS. 2 and 8, and the second semiconductor element TR2 may correspond to one of the second, third, fourth, fifth, sixth, seventh, and eighth transistors T2, T3, T4, T5, T6, T7, and T8 illustrated in FIGS. 2 and 8.

The second gate insulating layer GI2 may be disposed on the first gate insulating layer GI1, the first lower gate electrode 310, and the second lower gate electrode 320. The second gate insulating layer GI2 may cover the first lower gate electrode 310 and the second lower gate electrode 320. For example, the second gate insulating layer GI2 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other.

The upper gate electrode 410 may be disposed on the second gate insulating layer GI2. For example, the upper gate electrode 410 may include a metal, an alloy, a conductive metal oxide, a transparent conductive material, or the like. These may be used alone or in combination with each other.

The interlayer insulating layer ILD may be disposed on the second gate insulating layer GI2 and the upper gate electrode 410. The interlayer insulating layer ILD may cover the upper gate electrode 410. For example, the interlayer insulating layer ILD may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other.

The first, second, third, fourth, and fifth lower connection electrodes 510, 520, 530, 540, and 550 may be disposed on the interlayer insulating layer ILD. For example, each of the first, second, third, fourth, and fifth lower connection electrodes 510, 520, 530, 540, and 550 may include a metal, an alloy, a conductive metal oxide, a transparent conductive material, or the like. These may be used alone or in combination with each other. In an embodiment, each of the first, second, third, fourth, and fifth lower connection electrodes 510, 520, 530, 540, and 550 may include a low-resistance metal (e.g., aluminum, copper, and the like).

The first, second, third, fourth, and fifth lower connection electrodes 510, 520, 530, 540, and 550 may include a same material and may be disposed in a same layer.

The first lower connection electrode 510 may be connected to the first area A1 of the first active layer 210 through a contact hole penetrating the first gate insulating layer GI1, the second gate insulating layer GI2, and the interlayer insulating layer ILD. The first lower connection electrode 510 may be connected to the first lower metal layer 110 through a contact hole penetrating the buffer layer BUF, the first gate insulating layer GI1, the second gate insulating layer GI2, and the interlayer insulating layer ILD.

The second lower connection electrode 520 may be connected to the second area A2 of the first active layer 210 through a contact hole penetrating the first gate insulating layer GI1, the second gate insulating layer GI2, and the interlayer insulating layer ILD. The third lower connection electrode 530 may be connected to the first lower gate electrode 310 through a contact hole penetrating the first gate insulating layer GI1 and the second gate insulating layer GI2.

The fourth lower connection electrode 540 may be connected to the second lower gate electrode 320 through a contact hole penetrating the first gate insulating layer GI1, the second gate insulating layer GI2, and the interlayer insulating layer ILD. The fourth lower connection electrode 540 may be connected to the second lower metal layer 120 through a contact hole penetrating the buffer layer BUF, the first gate insulating layer GI1, the second gate insulating layer GI2, and the interlayer insulating layer ILD.

The fifth lower connection electrode 550 may be connected to the fourth area A4 of the second active layer 220 through a contact hole penetrating the first gate insulating layer GI1, the second gate insulating layer GI2, and the interlayer insulating layer ILD.

The first via insulating layer VIA1 may be disposed on the interlayer insulating layer ILD and the first, second, third, fourth, and fifth lower connection electrodes 510, 520, 530, 540, and 550. The first via insulating layer VIA1 may completely cover the first, second, third, fourth, and fifth lower connection electrodes 510, 520, 530, 540, and 550. For example, the first via insulating layer VIA1 may include an organic material such as a photoresist, a polyacrylic resin, a polyimide resin, a polyamide resin, a siloxane resin, an acrylic resin, an epoxy resin, and the like. These may be used alone or in combination with each other.

The first and second upper connection electrodes 610 and 620 may be disposed on the first via insulating layer VIA1. The first upper connection electrode 610 may be connected to the second lower connection electrode 520 through a contact hole penetrating the first via insulating layer VIAL The second upper connection electrode 620 may be connected to the fifth lower connection electrode 550 through a contact hole penetrating the first via insulating layer VIA1.

For example, each of the first and second upper connection electrodes 610 and 620 may include a metal, an alloy, a conductive metal oxide, a transparent conductive material, or the like. These may be used alone or in combination with each other. In an embodiment, each of the first and second upper connection electrodes 610 and 620 may include a low-resistance metal (e.g., aluminum, copper, and the like).

The first and second upper connection electrodes 610 and 620 may include a same material and may be disposed in a same layer.

The second via insulating layer VIA2 may be disposed on the first via insulating layer VIA1, the first upper connection electrode 610, and the second upper connection electrode 620. The second via insulating layer VIA2 may completely cover the first and second upper connection electrodes 610 and 620. For example, the second via insulation layer VIA2 may include an organic material such as a photoresist, a polyacrylic resin, a polyimide resin, a polyamide resin, a siloxane resin, an acrylic resin, an epoxy resin, and the like. These may be used alone or in combination with each other.

The third via insulating layer VIA3 may be disposed on the second via insulating layer VIA2. For example, the third via insulating layer VIA3 may include an organic material such as a photoresist, a polyacrylic resin, a polyimide resin, a polyamide resin, a siloxane resin, an acrylic resin, an epoxy resin, and the like. These may be used alone or in combination with each other.

In an embodiment, each of the first, second, and third via insulating layers VIA1, VIA2, and VIA3 may include photosensitive polyimide (PSPI). In an embodiment, a chemical mechanical polishing (CMP) process may be performed on each of the first, second, and third via insulating layers VIA1, VIA2, and VIA3. Accordingly, flatness of the first, second, and third via insulating layers VIA1, VIA2, and VIA3 may be improved. As a result, the thickness of the light emitting layer EML may be readily controlled, and the display quality of the display device DD may be improved.

The pixel electrode PE may be disposed on the third via insulating layer VIA3. The pixel electrode PE may be connected to the first upper connection electrode 610 through a contact hole penetrating the second and third via insulating layers VIA2 and VIA3. For example, the pixel electrode PE may include a metal, an alloy, a conductive metal oxide, a transparent conductive material, or the like. These may be used alone or in combination with each other. The pixel electrode PE may be an anode electrode. However, the disclosure is not limited thereto, and the pixel electrode PE may be a cathode electrode.

The pixel defining layer PDL may be disposed on the third via insulating layer VIA3 and the pixel electrode PE. The pixel defining layer PDL may have an opening exposing a portion of the pixel electrode PE. As the pixel defining layer PDL has an opening, the pixel defining layer PDL may define sub-pixels SPX emitting light. The pixel defining layer PDL may include an organic material or an inorganic material. For example, the pixel defining layer PDL may include an organic material such as a photoresist, a polyacrylic resin, a polyimide resin, a polyamide resin, a siloxane resin, an acrylic resin, an epoxy resin, and the like. These may be used alone or in combination with each other.

The light emitting layer EML may be disposed on the pixel electrode PE. In an embodiment, the light emitting layer EML may be disposed in the opening of the pixel defining layer PDL. The light emitting layer EML may include a light emitting material for emitting light. In an embodiment, the light emitting layer EML may be formed through an inkjet printing process.

For example, the light emitting layer EML may include an organic light emitting material and/or an inorganic light emitting material. In an embodiment, the light emitting layer EML may further include multiple quantum dots QD dispersed in the organic light emitting material and/or the inorganic light emitting material.

The common electrode CME may be disposed on the pixel defining layer PDL and the light emitting layer EML. For example, the common electrode CME may include a metal, an alloy, a metal nitride, a conductive metal oxide, a transparent conductive material, or the like. These may be used alone or in combination with each other. The common electrode CME may be a cathode electrode. However, the disclosure is not limited thereto, and the common electrode CME may be an anode electrode.

Accordingly, the light emitting element LED including the pixel electrode PE, the light emitting layer EML, and the common electrode CME may be defined.

The encapsulation layer ENC may be disposed on the common electrode CME. The encapsulation layer ENC may prevent impurities, moisture, and the like from permeating to the light emitting element LED from the outside. The encapsulation layer ENC may include at least one inorganic encapsulation layer and at least one organic encapsulation layer. For example, the inorganic encapsulation layer may include silicon oxide, silicon nitride, silicon oxynitride, or the like, and the organic encapsulation layer may include a polymer cured material such as polyacrylate, and the like.

The light blocking layer BM may be disposed on the encapsulation layer ENC. The light blocking layer BM may overlap the pixel defining layer PDL in a plan view. An opening overlapping the light emitting layer EML may be defined in the light blocking layer BM. For example, the light blocking layer BM may include an inorganic material and/or an organic material including a light blocking material such as black pigment, black dye, carbon black, and the like.

The color filter CF may be disposed on the encapsulation layer ENC. In an embodiment, the color filter CF may be disposed in the opening of the light blocking layer BM. For example, the color filter CF may be one of a red color filter, a blue color filter, and a red color filter. The color filter CF may include a photosensitive resin or a color photoresist.

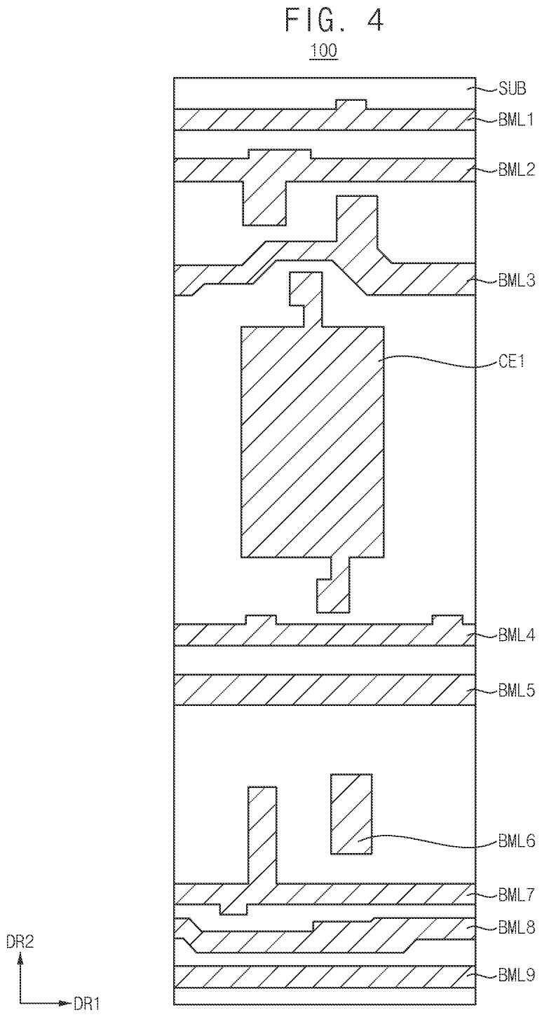

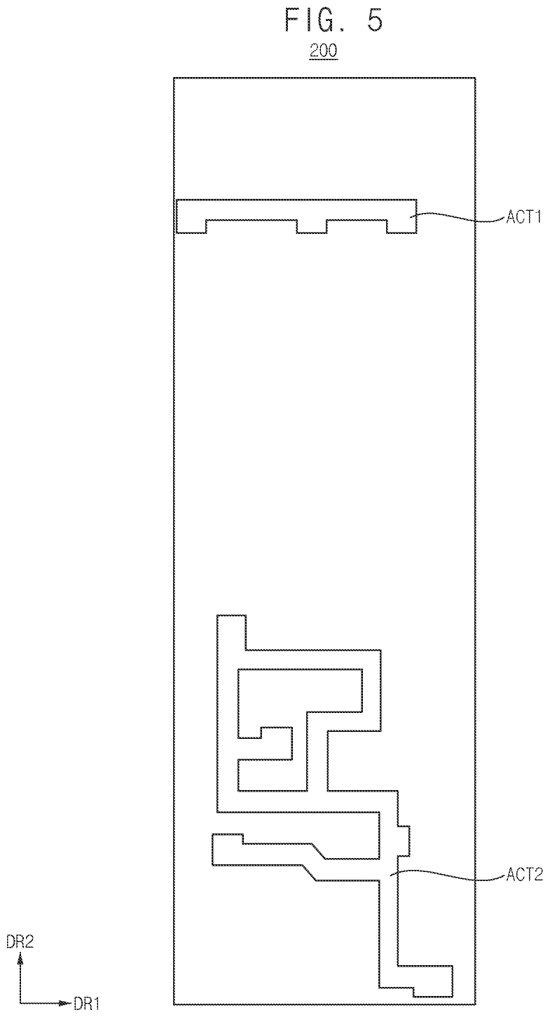

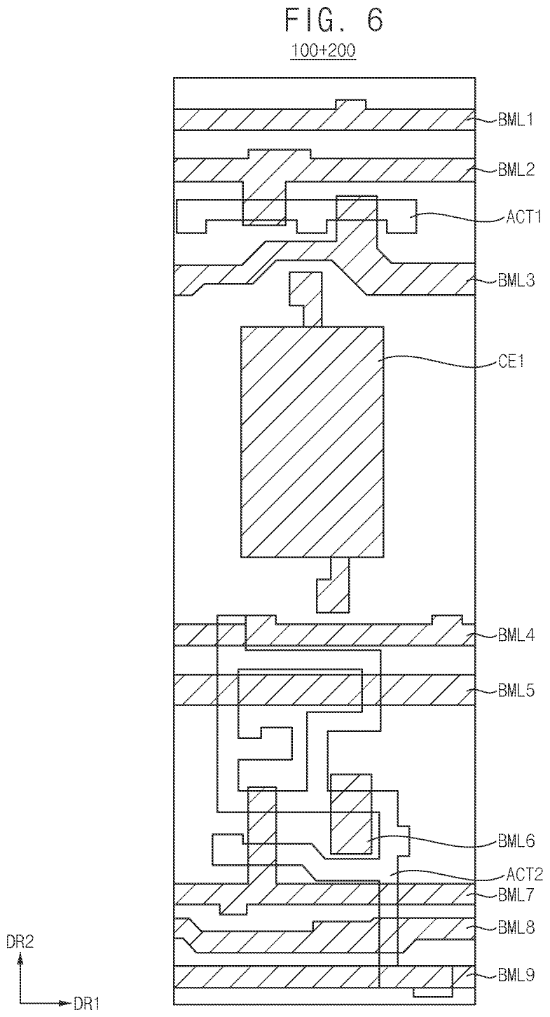

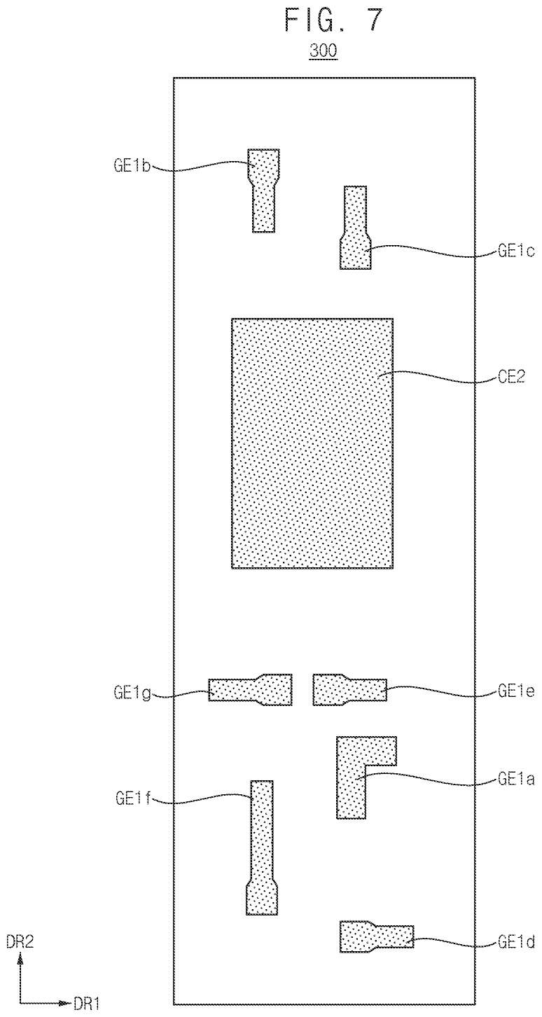

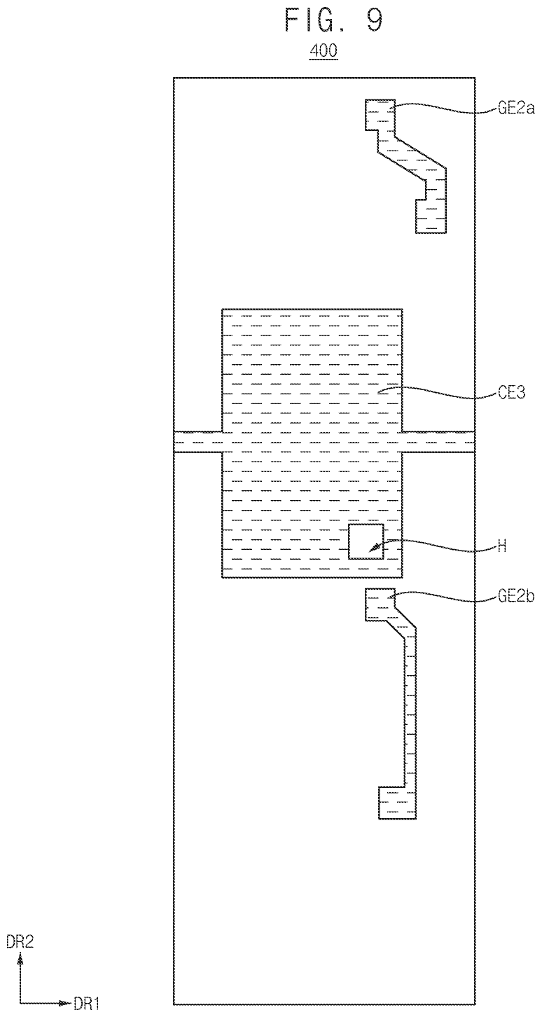

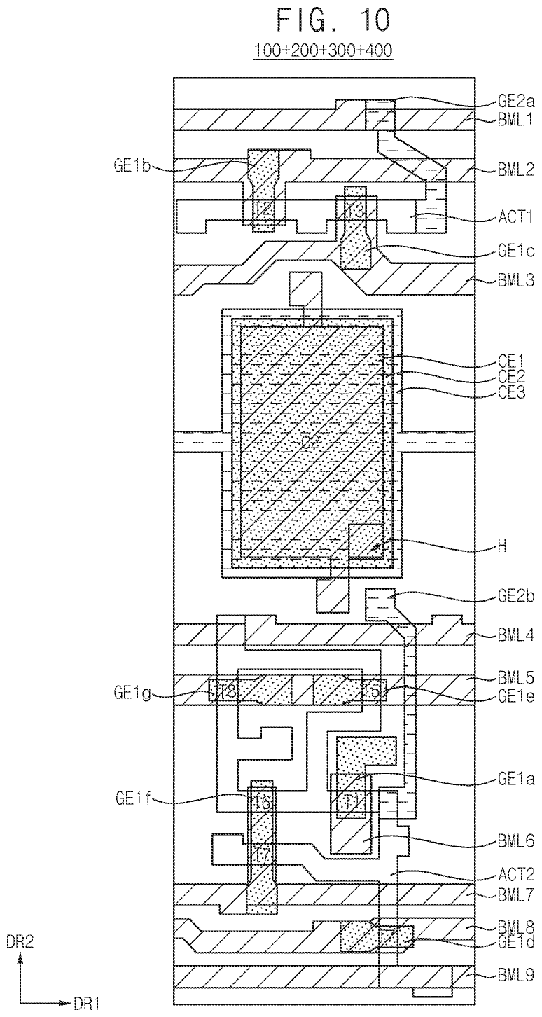

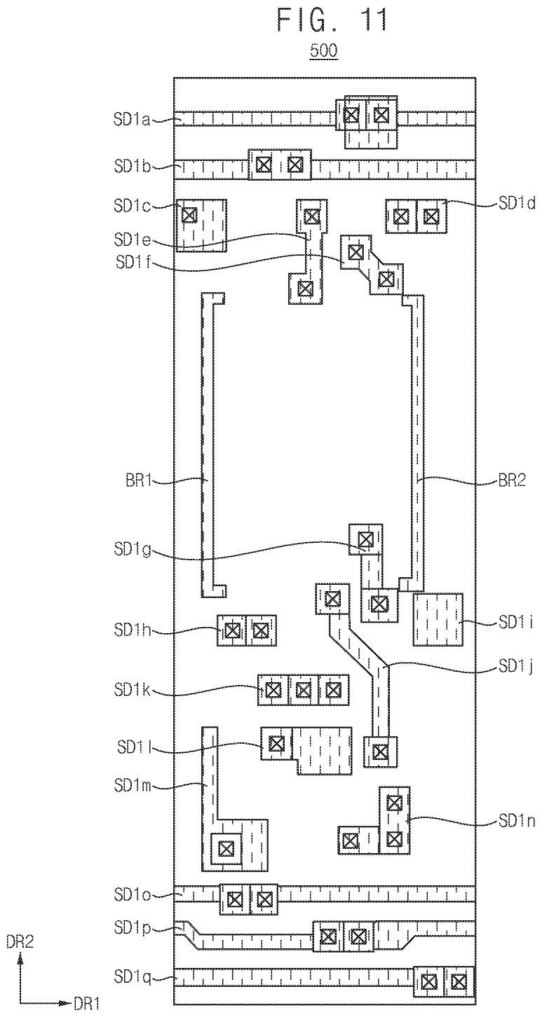

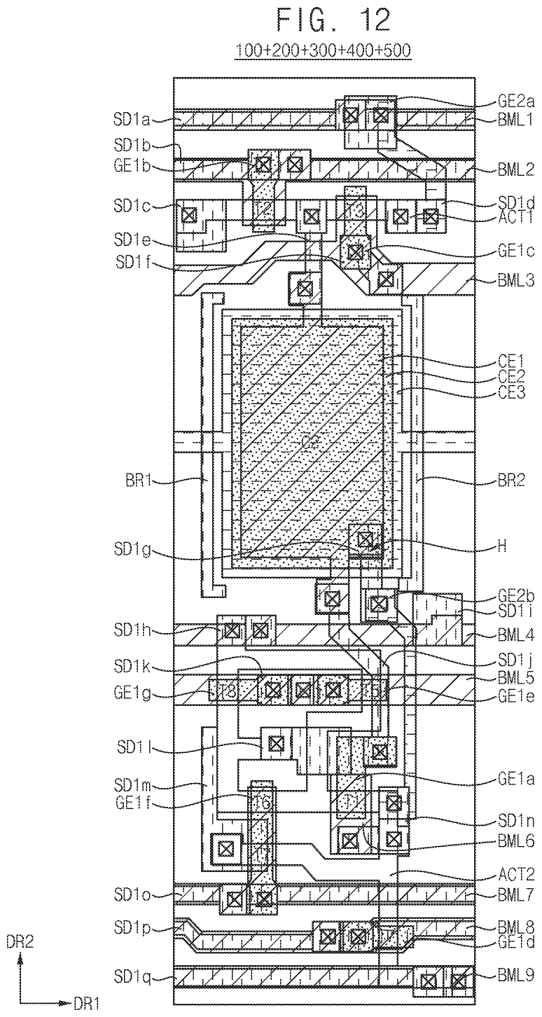

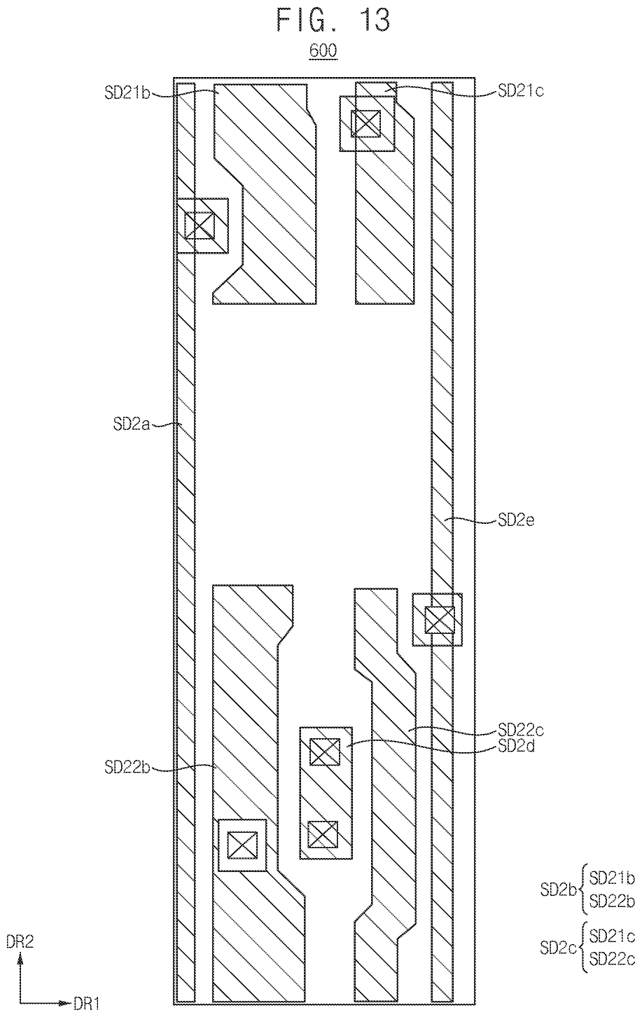

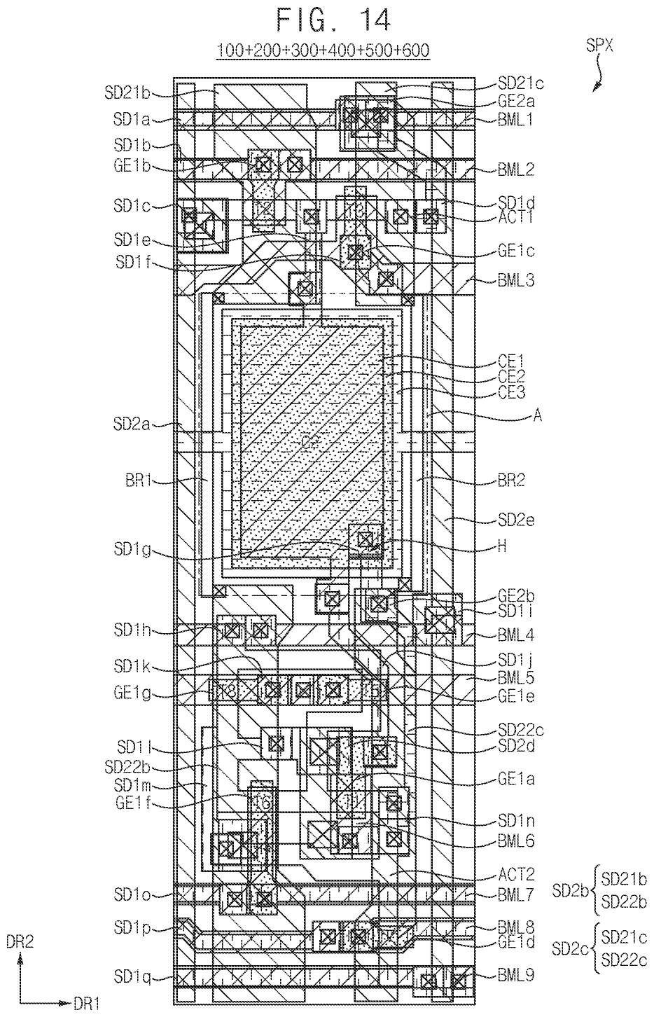

FIGS. 4, 5, 6, 7, 8, 9, 10, 11, 12, 13, and 14 are layout views for illustrating one sub-pixel of the display device of FIG. 1. For example, the sub-pixel SPX illustrated in FIG. 14 may be one of the first, second, and third sub-pixels SPX1, SPX2, and SPX3 of FIG. 1.

Referring to FIGS. 1 and 4, the display device DD according to an embodiment of the disclosure may include a first conductive layer 100 disposed on the substrate SUB.

The first conductive layer 100 may include first, second, third, fourth, fifth, sixth, seventh, and eighth lower lines BML1, BML2, BML3, BML4, BML5, BML7, BML8, and BML9, a connection pattern BML6, and a first capacitor electrode CE1. The first, second, third, fourth, fifth, sixth, seventh, and eighth lower lines BML1, BML2, BML3, BML4, BML5, BML7, BML8, and BML9, the connection pattern BML6, and the first capacitor electrode CE1 may include a same material and may be disposed in a same layer.

The first lower line BML1 may extend in the first direction DR1. A reference voltage (e.g., the reference voltage VREF of FIG. 2) may be applied to the first lower line BML1.

The second lower line BML2 may include a first portion extending in the first direction DR1 and a second portion protruding in the second direction DR2 from the first portion. A first control signal (e.g., the first control signal GW of FIG. 2) may be applied to the second lower line BML2.

The third lower line BML3 may include a first portion extending in the first direction DR1 and a second portion protruding from the first portion in the second direction. A second control signal (e.g., the second control signal GR of FIG. 2) may be applied to the third lower line BML3.

The fourth lower line BML4 may extend in the first direction DR1. A second initialization voltage (e.g., the second initialization voltage VINT2 of FIG. 2) may be applied to the fourth lower line BML4.

The fifth lower line BML5 may extend in the first direction DR1. A third control signal (e.g., the third control signal GC of FIG. 2) may be applied to the fifth lower line BML5.

Each of the first capacitor electrode CE1 and the connection pattern BML6 may have an island shape in a plan view.

The sixth lower line BML7 may include a first portion extending in the first direction DR1 and a second portion protruding in the second direction DR2 from the first portion. A light emitting control signal (e.g., the light emitting control signal EM of FIG. 2) may be applied to the sixth lower line BML7.

The seventh lower line BML8 may extend in the first direction DR1. A fourth control signal (e.g., the fourth control signal GI of FIG. 2) may be applied to the seventh lower line BML8.

The eighth lower line BML9 may extend in the first direction DR1. A first initialization voltage (e.g., the first initialization voltage VINT1 of FIG. 2) may be applied to the eighth lower line BML9.

The first conductive layer 100 and the first and second lower metal layers 110 and 120 illustrated in FIG. 3 may include a same material and may be disposed in a same layer.

Referring to FIGS. 1, 4, 5, and 6, the display device DD according to an embodiment of the disclosure may further include an active layer 200. The active layer 200 may be disposed on the first conductive layer 100. For example, a buffer layer (e.g., the buffer layer BUF of FIG. 3) may be disposed on the first conductive layer 100, and the active layer 200 may be disposed on the buffer layer.

The active layer 200 may include a first active pattern ACT1 and a second active pattern ACT2. The first active pattern ACT1 and the second active pattern ACT2 may include a same material and may be disposed in a same layer.

The first active pattern ACT1 may extend in the first direction DR1. The first active pattern ACT1 may partially overlap each of the second and third lower lines BML2 and BML3 in the plan view. The second active pattern ACT2 may partially overlap each of the fourth, fifth, sixth, seventh, and eighth lower lines BML4, BML5, BML7, BML8, and BML9 and the connection pattern BML6 in the plan view.

The active layer 200 and the first and second active layers 210 and 220 illustrated in FIG. 3 may include a same material and may be disposed in a same layer. For example, the active layer 200 may include a metal oxide semiconductor.

Referring to FIGS. 1, 4, 5, 6, 7, and 8, the display device DD according to an embodiment of the disclosure may further include a second conductive layer 300. The second conductive layer 300 may be disposed on the active layer 200. For example, a first gate insulating layer (e.g., the first gate insulating layer GI1 of FIG. 3) may be disposed on the active layer 200, and the second conductive layer 300 may be disposed on the first gate insulating layer.

The second conductive layer 300 may include first, second, third, fourth, fifth, sixth, and seventh lower gate patterns GE1a, GE1b, GE1c, GE1d, GE1e, GE1f, and GE1g and a second capacitor electrode CE2. The first, second, third, fourth, fifth, sixth, and seventh lower gate patterns GE1a, GE1b, GE1c, GE1d, GE1e, GE1f, and GE1g and the second capacitor electrode CE2 may include a same material and may be disposed in a same layer.

The first lower gate pattern GE1a may include a portion extending in the first direction DR1 and a portion extending in the second direction DR2. The first lower gate pattern GE1a may partially overlap the connection pattern BML6 and the second active pattern ACT2 in the plan view. The first lower gate pattern GE1a and the portion of the second active pattern ACT2 overlapping the first lower gate pattern GE1a may constitute the first transistor T1.

The second lower gate pattern GE1b may extend in the second direction DR2. The second lower gate pattern GE1b may partially overlap each of the second lower line BML2 and the first active pattern ACT1 in the plan view. The second lower gate pattern GE1b and the portion of the first active pattern ACT1 overlapping the second lower gate pattern GE1b may constitute the second transistor T2.

The third lower gate pattern GE1c may extend in the second direction DR2. The third lower gate pattern GE1c may partially overlap each of the third lower line BML3 and the first active pattern ACT1 in the plan view. The third lower gate pattern GE1c and the portion of the first active pattern ACT1 overlapping the third lower gate pattern GE1c may constitute the third transistor T3.

The fourth lower gate pattern GE1d may extend in the first direction DR1. The fourth lower gate pattern GE1d may partially overlap each of the seventh lower line BML8 and the second active pattern ACT2 in the plan view. The fourth lower gate pattern GE1d and the portion of the second active pattern ACT2 overlapping the fourth lower gate pattern GE1d may constitute the fourth transistor T4.

The fifth lower gate pattern GE1e may extend in the first direction DR1. The fifth lower gate pattern GE1e may partially overlap each of the fifth lower line BML5 and the second active pattern ACT2 in the plan view. The fifth lower gate pattern GE1e and the portion of the second active pattern ACT2 overlapping the fifth lower gate pattern GE1e may constitute the fifth transistor T5.

The sixth lower gate pattern GE1f may extend in the second direction DR2. The sixth lower gate pattern GE1f may partially overlap each of the sixth lower line BML7 and the second active pattern ACT2 in the plan view. The sixth lower gate pattern GE1f and a first portion of the second active pattern overlapping the sixth lower gate pattern GE1f may constitute the sixth transistor T6. The sixth lower gate pattern GE1f and a second portion of the second active pattern ACT2 overlapping the sixth lower gate pattern GE1f may constitute the seventh transistor T7.

The seventh lower gate pattern GE1g may extend in the first direction DR1. The seventh lower gate pattern GE1g may partially overlap the fifth lower line BML5 and the second active pattern ACT2 in the plan view. The seventh lower gate pattern GE1g and a portion of the second active pattern ACT2 overlapping the seventh lower gate pattern GE1g may constitute the eighth transistor T8.

The second capacitor electrode CE2 may overlap the first capacitor electrode CE1 in the plan view. The second capacitor electrode CE2 and the first capacitor electrode CE1 may constitute the first capacitor C1. In an embodiment, the first capacitor C1 may be a storage capacitor.

The second conductive layer 300 and the first and second lower gate electrodes 310 and 320 illustrated in FIG. 3 may include a same material and may be disposed in a same layer.

Referring to FIGS. 1, 4, 5, 6, 7, 8, 9, and 10, the display device DD according to an embodiment of the disclosure may further include a third conductive layer 400. The third conductive layer 400 may be disposed on the second conductive layer 300. For example, a second gate insulating layer (e.g., the second gate insulating layer GI2 of FIG. 3) may be disposed on the second conductive layer 300, and the third conductive layer 400 may be disposed on the second gate insulating layer.

The third conductive layer 400 may include a first upper gate pattern GE2a, a second upper gate pattern GE2b, and a third capacitor electrode CE3. The first upper gate pattern GE2a, the second upper gate pattern GE2b, and the third capacitor electrode CE3 may include a same material and may be disposed in a same layer.

Each of the first and second upper gate patterns GE2a and GE2b may extend in the second direction DR2. The first upper gate pattern GE2a may overlap a portion of the first active pattern ACT1 in the plan view and the second upper gate pattern GE2b may overlap a portion of the second active pattern ACT2 in the plan view.

The third capacitor electrode CE3 may overlap the first and second capacitor electrodes CE1 and CE2 in the plan view. The third capacitor electrode CE3 and the second capacitor electrode CE2 may constitute the second capacitor C2. In an embodiment, the second capacitor C2 may be a hold capacitor.

A hole H penetrating the third capacitor electrode CE3 may be formed in the third capacitor electrode CE3. The hole H may overlap the first and second capacitor electrodes CE1 and CE2 in the plan view.

The third conductive layer 400 and the upper gate electrode 410 illustrated in FIG. 3 may include a same material and may be disposed in a same layer.

Referring to FIGS. 1, 4, 5, 6, 7, 8, 9, 10, 11, and 12, the display device DD according to an embodiment of the disclosure may further include a fourth conductive layer 500. The fourth conductive layer 500 may be disposed on the third conductive layer 400. For example, an interlayer insulating layer (e.g., the interlayer insulating layer ILD of FIG. 3) may be disposed on the third conductive layer 400, and the fourth conductive layer 500 may be disposed on the interlayer insulating layer.

The fourth conductive layer 500 may include first, second, third, fourth, and fifth lower connection lines SD1a, SD1b, SD1o, SD1p, and SD1q, first, second, third, fourth, fifth, sixth, seventh, eighth, ninth, tenth, and eleventh lower connection patterns SD1c, SD1d, SDle, SD1f, SD1g, SD1h, SD1i, SD1j, SD1k, SD1l, SD1m, and SD1n, a first bridge pattern BR1, and a second bridge pattern BR2. The first, second, third, fourth, and fifth lower connection lines SD1a, SD1b, SD1o, SD1p, and SD1q, the first, second, third, fourth, fifth, sixth, seventh, eighth, ninth, tenth, and eleventh lower connection patterns SD1c, SD1d, SD1e, SD1f, SD1g, SD1h, SD1i, SD1j, SD1k, SD1l, SD1m, and SD1n, the first bridge pattern BR1, and the second bridge pattern BR2 may include a same material and may be disposed in a same layer.

The first lower connection line SD1a may extend in the first direction DR1. The first lower connection line SD1a may entirely overlap the first lower line BML1 in the plan view. The first lower connection line SD1a may contact the first lower line BML1 and the first upper gate pattern GE2a. The first lower connection line SD1a may provide a reference voltage (e.g., the reference voltage VREF of FIG. 2) to the first active pattern ACT1 through the first lower line BML1 and the upper gate pattern GE2a.

The second lower connection line SD1b may extend in the first direction DR1. The second lower connection line SD1b may entirely overlap the second lower line BML2 in the plan view. The second lower connection line SD1b may contact the second lower line BML2 and the second lower gate pattern GE2a. The second lower connection line SD1b may receive the first control signal (e.g., the first control signal GW of FIG. 2) through the second lower line BML2. The first control signal may be applied to the second lower gate pattern GE2a through the second lower connection line SD1b.

The third lower connection line SD10 may extend in the first direction DR1. The third lower connection line SD10 may entirely overlap the sixth lower line BML7 in the plan view. The third lower connection line SD10 may contact the sixth lower line BML7 and the sixth lower gate pattern GE1f. The third lower connection line SD10 may receive a light emitting control signal (e.g., the light emitting control signal EM of FIG. 2) through the sixth lower line BML7. The light emitting control signal may be applied to the sixth lower gate pattern GE1f through the third lower connection line SD1o.

The fourth lower connection line SD1p may extend in the first direction DR1. The fourth lower connection line SD1p may entirely overlap the seventh lower line BML8 in the plan view. The fourth lower connection line SD1p may contact the seventh lower line BML8 and the fourth lower gate pattern GE1d. The fourth lower connection line SD1p may receive a fourth control signal (e.g., the fourth control signal GI of FIG. 2) through the seventh lower line BML8. The fourth control signal may be applied to the fourth lower gate pattern GE1d through the fourth lower connection line SD1p.

The fifth lower connection line SD1q may extend in the first direction DR1. The fifth lower connection line SD1q may entirely overlap the eighth lower connection line BML9 in the plan view. The fifth lower connection line SD1q may contact each of the eighth lower connection line BML9 and the second active pattern ACT2. The fifth lower connection line SD1q may provide a first initialization voltage (e.g., a first initialization voltage VINT1 of FIG. 2) to the second active pattern ACT2.

The first lower connection pattern SD1c may contact the first active pattern ACT1. The second lower connection pattern SD1d may contact the first active pattern ACT1 and the first upper gate pattern GE2a.

The third lower connection pattern SD1e may contact the first active pattern ACT1 and the first capacitor electrode CE1. The fourth lower connection pattern SD1f may contact the third lower line BML3 and the third lower gate pattern GE1c.

The fifth lower connection pattern SD1g may contact the second capacitor electrode CE2 through the hole H of the third capacitor electrode CE3. The fifth lower connection pattern SD1g may contact the second upper gate pattern GE2b.

The sixth lower connection pattern SD1h may contact the second active pattern ACT2 and the fourth lower line BML4. The sixth lower connection pattern SD1h may provide a second initialization voltage (e.g., the second initialization voltage VINT2 of FIG. 2) to the second active pattern ACT2.

The seventh lower connection pattern SD1i may partially overlap the fourth lower interconnection BML4 in the plan view. The eighth lower connection pattern SD1j may contact the first capacitor electrode CE1 and the first lower gate pattern GE1a.

The eighth lower connection pattern SD1k may contact the fifth lower line BML5, the fifth lower gate pattern GE1e, and the seventh lower gate pattern GE1g. The ninth lower connection pattern SD11 may contact the second active pattern ACT2.

The tenth lower connection pattern SD1m may contact the second active pattern ACT2. The eleventh lower connection pattern SD1n may contact the connection pattern BML6, the second active pattern ACT2, and the second upper gate pattern GE2b.

Each of the first and second bridge patterns BR1 and BR2 may extend in the second direction DR2. The first bridge pattern BR1 and the second bridge pattern BR2 may prevent coupling between a gate and an anode. A detailed description of the first bridge pattern BR1 and the second bridge pattern BR2 will be described below.

The fourth conductive layer 500 and the first, second, third, fourth, and fifth lower connection electrodes 510, 520, 530, 540, and 550 illustrated in FIG. 3 may include a same material and may be disposed in a same layer. In an embodiment, the fourth conductive layer 500 may include a low-resistance metal (e.g., aluminum, copper, and the like).

Referring to FIGS. 1, 4, 5, 6, 7, 8, 9, 10, 11, 12, 13, and 14, the display device DD according to an embodiment of the disclosure may further include a fifth conductive layer 600. The fifth conductive layer 600 may be disposed on the fourth conductive layer 500. For example, a first via insulating layer (e.g., the first via insulating layer VIA1 of FIG. 3) may be disposed on the fourth conductive layer 500, and the fifth conductive layer 600 may be disposed on the first via insulating layer.

The fifth conductive layer 600 may include a data line SD2a, first, second, and third voltage lines SD2b, SD2c and SD2e, and an anode connection pattern SD2d. The data line SD2a, the first, second, and third voltage lines SD2b, SD2c, and SD2e, and the anode connection pattern SD2d may include a same material and may be disposed in a same layer.

The data line SD2a may extend in the second direction DR2. The data line SD2a may contact the first lower connection pattern SD1c. The data line SD2a may provide a data voltage (e.g., the data voltage DATA of FIG. 2) to the first active pattern ACT1.

The first voltage line SD2b may include a first portion SD21b and a second portion SD22b each extending in the second direction DR2. Each of the first portion SD21b and the second portion SD22b of the first voltage line SD2b may contact the first bridge pattern BR1. The second part SD22b of the first voltage line SD2b may contact the tenth lower connection pattern SD1m. The first voltage line SD2b may provide a common voltage (e.g., the common voltage ELVSS of FIG. 2) to the second active pattern ACT2. For example, the first voltage line SD2b may be defined as a common voltage line to which the common voltage is applied. A detailed description of the first voltage line SD2b will be described below.

The second voltage line SD2c may include a first portion SD21c and a second portion SD22c each extending in the second direction DR2. Each of the first portion SD21c and the second portion SD22c of the second voltage line SD2c may contact the second bridge pattern BR2. The first portion SD21c of the second voltage line SD2c may contact the first lower connection line SD1a. The second voltage line SD2c may provide a reference voltage (e.g., the reference voltage VREF of FIG. 2) to the first active pattern ACT1. The second voltage line SD2c may be defined as a reference voltage line to which the reference voltage is applied. A detailed description of the second voltage line SD2c will be described below.

The third voltage line SD2e may extend in the second direction DR2. The third voltage line SD2e may contact the seventh lower connection pattern SD1i. The third voltage line SD2e may provide a second initialization voltage (e.g., the second initialization voltage VINT2 of FIG. 2) to the second active pattern ACT2.

The anode connection pattern SD2d may contact the ninth lower connection pattern SD11. The anode connection pattern SD2d may contact the pixel electrode PE illustrated in FIG. 3. Accordingly, the anode connection pattern SD2d may electrically connect the second active pattern ACT2 and the light emitting element LED. For example, the light emitting element LED illustrated in FIG. 3 may be disposed on the layout drawing illustrated in FIG. 14.

The fifth conductive layer 600 and the first and second upper connection electrodes 610 and 620 illustrated in FIG. 3 may include a same material and may be disposed in a same layer. In an embodiment, the fifth conductive layer 600 may include a low-resistance metal (e.g., aluminum, copper, and the like).

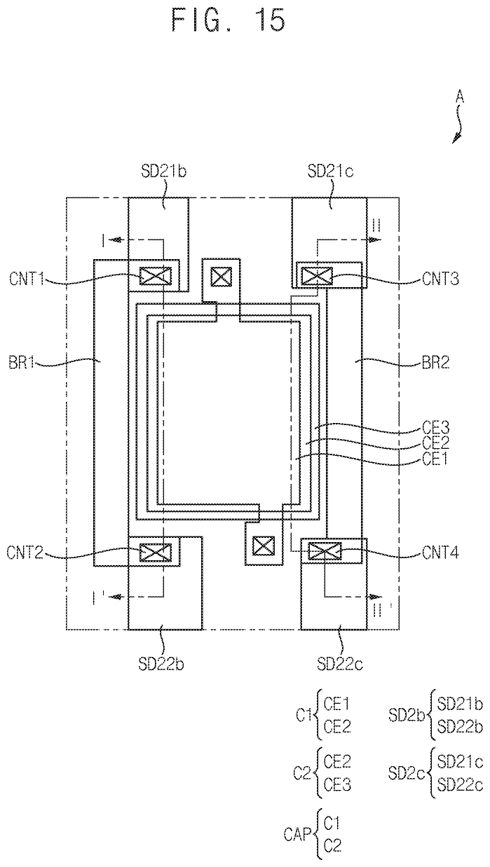

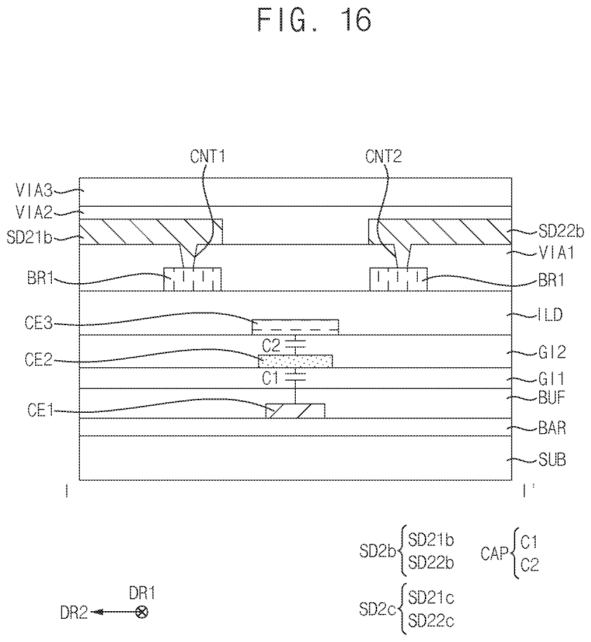

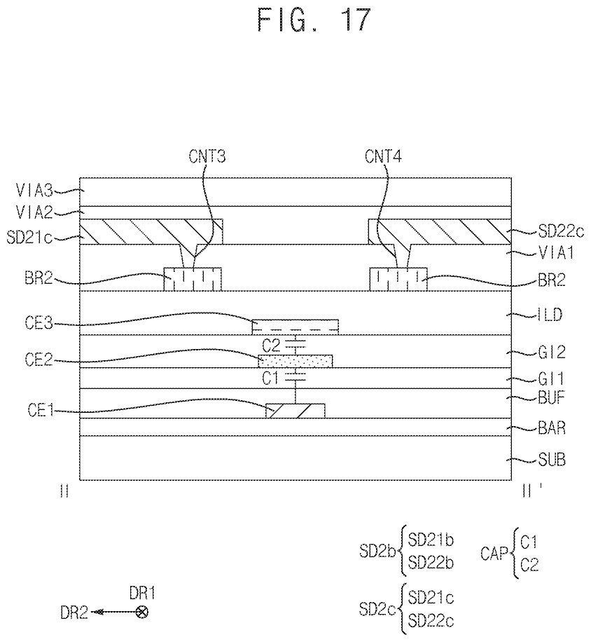

FIG. 15 is an enlarged plan view of area A of FIG. 14. FIG. 16 is a schematic cross-sectional view taken along line I-I′ of FIG. 15. FIG. 17 is a schematic cross-sectional view taken along line II-II′ of FIG. 15. For example, FIG. 15 is an enlarged plan view of the first, second, and third capacitor electrodes CE1, CE2, and CE3, the first and second bridge patterns BR1 and BR2, the first voltage line SD2b, and the second voltage line SD2c of FIG. 14. Hereinafter, descriptions overlapping the display device DD described with reference to FIGS. 4, 5, 6, 7, 8, 9, 10, 11, 12, 13, and 14 will be omitted or simplified.

Referring to FIGS. 15, 16, and 17, as described above, the second capacitor electrode CE2 may constitute the first capacitor C1 together with the first capacitor electrode CE1 and the third capacitor electrode CE3 may constitute the second capacitor C2 together with the second capacitor electrode CE2. In an embodiment, the first, second, and third capacitor electrodes CE1, CE2, and CE3 may overlap with each other in the plan view. Accordingly, the first capacitor C1 and the second capacitor C2 may define one capacitor CAP.

The first voltage line SD2b may be disposed on the first via insulating layer VIA1 and may include the first portion SD21b and the second portion SD22b. In an embodiment, each of the first portion SD21b and the second portion SD22b of the first voltage line SD2b may be spaced apart from the first and second capacitors C1 and C2 in the plan view. For example, the first portion SD21b and the second portion SD22b of the first voltage line SD2b may not overlap the first and second capacitors C1 and C2 in the plan view.

The second voltage line SD2c may be disposed on the first via insulating layer VIA1 and may include the first portion SD21c and the second portion SD22c. In an embodiment, each of the first portion SD21c and the second portion SD22c of the second voltage line SD2c may be spaced apart from the first and second capacitors C1 and C2 in a plan view. For example, the first portion SD21c and the second portion SD22c of the second voltage line SD2c may not overlap the first and second capacitors C1 and C2 in the plan view.

As the first and second voltage lines SD2b and SD2c are spaced apart from the capacitor CAP in the plan view, a step difference between an area where the capacitor CAP is disposed and an area where the capacitor CAP is not disposed may be improved.

The first bridge pattern BR1 may be disposed on the interlayer insulating layer ILD and may connect the first portion SD21b and the second portion SD22b of the first voltage line SD2b. For example, the first voltage line SD2b may be connected to the first bridge pattern BR1 through contact holes CNT1 and CNT2 penetrating the first via insulating layer VIAL In an embodiment, the first bridge pattern BR1 may be spaced apart from the first and second capacitors C1 and C2 in the first direction DR1 in the plan view. For example, the first bridge pattern BR1 may have a “C” shape in the plan view.

The second bridge pattern BR2 may be disposed on the interlayer insulating layer ILD and may connect the first portion SD21c and the second portion SD22c of the second voltage line SD2c. For example, the second voltage line SD2c may be connected to the second bridge pattern BR2 through contact holes CNT3 and CNT24 penetrating the first via insulating layer VIAL The second bridge pattern BR2 may be spaced apart from the first and second capacitors C1 and C2 in a first direction DR1 in the plan view. For example, the second bridge pattern BR2 may have a “C” shape rotated by about 180 degrees in the plan view.

Referring back to FIGS. 1, 2, 3, 4, 5, 6, 7, 8, 9, 10, 11, 12, 13, 14, 15, 16, and 17, the display device DD according to an embodiment of the disclosure may include the first capacitor electrode CE1 disposed on the substrate SUB, the second capacitor electrode CE2 overlapping the first capacitor electrode CE1 and constituting the first capacitor C1 (e.g., a storage capacitor) together with the first capacitor electrode CE1, the third capacitor electrode CE3 overlapping the second capacitor electrode CE2 and constituting the second capacitor C2 (e.g., a hold capacitor) together with the second capacitor electrode CE2, the voltage line SD2b and SD2c including the first portion SD21b and SD21c and the second portion SD22b and SD22c spaced apart from the first and second capacitors C1 and C2 in the plan view, and the bridge pattern BR1 and BR2 disposed on a different layer from the voltage line SD2b and SD2c and connecting the first portion SD21b and SD21c and the second portion SD22b and SD22c of the voltage line SD2b and SD2c. Accordingly, the step difference between an area in which the capacitor CAP is disposed and an area in which the capacitor CAP is not disposed may be improved. The thickness of the light emitting layer EML may be readily controlled, and the display quality of the display device DD may be improved.

The disclosure may be applied to various display devices. For example, the disclosure may be applicable to various display devices such as display devices for vehicles, ships, and aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first capacitor electrode disposed on a substrate;
a second capacitor electrode disposed on the first capacitor electrode and constituting a first capacitor together with the first capacitor electrode;
a third capacitor electrode disposed on the second capacitor electrode and constituting a second capacitor together with the second capacitor electrode;
a first voltage line including a first portion and a second portion spaced apart from the first and second capacitors in a plan view; and
a first bridge pattern electrically connecting the first portion and the second portion of the first voltage line, wherein
the first voltage line and the third capacitor electrode are disposed in different layers, and
the first bridge pattern and the first voltage line are disposed in different layers.

2. The display device of claim 1, wherein
the first capacitor is a storage capacitor, and
the second capacitor is a hold capacitor.

3. The display device of claim 1, wherein the first, second, and third capacitor electrodes overlap with each other in a plan view.

4. The display device of claim 1, wherein the first voltage line is a common voltage line to which a common voltage is applied.

5. The display device of claim 1, wherein the first bridge pattern has a C shape in a plan view.

6. The display device of claim 1, wherein each of the first bridge pattern and the first voltage line includes a metal having low resistance.

7. The display device of claim 1, further comprising:
a second voltage line including a first portion and a second portion spaced apart from the first and second capacitors in a plan view; and
a second bridge pattern electrically connecting the first portion and the second portion of the second voltage line, wherein
the second voltage line and the third capacitor electrode are disposed in different layers, and
the second bridge pattern and the second voltage line are disposed in different layers.

8. The display device of claim 7, wherein the second voltage line is a reference voltage line to which a reference voltage is applied.

9. The display device of claim 7, wherein the second bridge pattern has a C shape rotated by about 180 degrees in a plan view.

10. The display device of claim 7, wherein each of the first bridge pattern and the second bridge pattern is spaced apart from the first and second capacitors in a plan view.

11. The display device of claim 7, wherein each of the second bridge pattern and the second voltage line includes a metal having low resistance.

12. The display device of claim 1, further comprising:
a lower metal layer disposed on the substrate;
an active layer disposed on the lower metal layer and including a metal oxide semiconductor;
a lower gate electrode disposed on the active layer;
an upper gate electrode disposed on the lower gate electrode;
a lower connection electrode disposed on the upper gate electrode; and
an upper connection electrode disposed on the lower connection electrode.

13. The display device of claim 12, wherein
the first capacitor electrode and the lower metal layer are disposed in a same layer,
the second capacitor electrode and the lower gate electrode are disposed in a same layer, and
the third capacitor electrode and the upper gate electrode are disposed in a same layer.

14. The display device of claim 12, wherein
the first voltage line and the lower connection electrode are disposed in a same layer, and
the first bridge pattern and the upper connection electrode are disposed in a same layer.

15. The display device of claim 12, further comprising:
a light emitting element including a pixel electrode, a light emitting layer, and a common electrode sequentially disposed on the upper connection electrode,
wherein the light emitting layer includes a light emitting material and a plurality of quantum dots dispersed in the light emitting material.

16. The display device of claim 15, further comprising:
a light blocking layer disposed on the light emitting element and including an opening overlapping the light emitting layer in a plan view; and
a color filter disposed in the opening.

17. The display device of claim 12, further comprising:
a first via insulating layer covering the lower connection electrode; and
a second via insulating layer disposed on the first via insulating layer and covering the upper connection electrode,
wherein each of the first via insulating layer and the second via insulating layer includes photosensitive polyimide (PSPI).

18. A display device comprising:
a first capacitor electrode disposed on a substrate;
a second capacitor electrode disposed on the first capacitor electrode and constituting a first capacitor together with the first capacitor electrode;
a third capacitor electrode disposed on the second capacitor electrode and constituting a second capacitor together with the second capacitor electrode;
a first voltage line including a first portion and a second portion spaced apart from the first and second capacitors in a plan view, each of the first portion and the second portion extending in a first direction; and
a first bridge pattern electrically connecting the first portion and the second portion of the first voltage line and spaced apart from the first and second capacitors in a plan view in a second direction intersecting the first direction, wherein
the first voltage line and the third capacitor electrode are disposed in different layers, and
the first bridge pattern and the first voltage line are disposed in different layers.

19. The display device of claim 18, wherein the first voltage line is a common voltage line to which a common voltage is applied.

20. The display device of claim 18, further comprising:
a second voltage line including a first portion and a second portion spaced apart from the first and second capacitors in a plan view, each of the first portion and the second portion of the second voltage line extending in the first direction; and
a second bridge pattern electrically connecting the first portion and the second portion of the second voltage line and spaced apart from the first and second capacitors in a plan view in the second direction,
wherein the second voltage line includes a reference voltage line to which a reference voltage is applied,
the second voltage line and the third capacitor electrode are disposed in different layers, and
the second bridge pattern and the second voltage line are disposed in different layers.
